(19) United States
(12) Patent Application Publication
(10) Pub. No.: US 2025/0373211 A1
(43) Pub. Date: Dec. 4, 2025

(54) 90° COUPLER

(71) Applicant: Murata Manufacturing Co., Ltd., Nagaokakyo-shi (JP)

(72) Inventor: Hisanori NAMIE, Nagaokakyo-shi (JP)

(21) Appl. No.: 19/223,094

(22) Filed: May 30, 2025

(30) Foreign Application Priority Data
May 31, 2024 (JP) 2024088876

(51) Int. Cl. H03F 1/56; H03F 1/02; H03F 3/24

(52) U.S. Cl. CPC H03F 1/565; H03F 1/0288; H03F 3/245; H03F 2200/198; H03F 2200/451

(57) ABSTRACT

A 90° coupler includes a first capacitor having a first end connected to a first terminal and a second end connected to a first amplifier, a first inductor having a first end connected to the first terminal and a second end connected to a second amplifier, a second inductor having a first end connected to the second end of the first capacitor and a second end connected to the ground through a resistance element and electromagnetically coupling to the first inductor, and a second capacitor having a first end connected to the first terminal and a second end connected to the second end of the second inductor.

### CROSS REFERENCE TO RELATED APPLICATION

This application claims priority from Japanese Patent Application No. 2024-088876, filed on May 31, 2024. The content of this application is incorporated herein by reference in its entirety.

### BACKGROUND OF THE DISCLOSURE

### 1. Field of the Disclosure

The present disclosure relates to a 90° coupler.

### 2. Description of the Related Art

Splitting circuits which split radio frequency (RF) signals include a 90° coupler (for example, see FIG. 2). In a power amplifier circuit 901 illustrated in FIG. 2, a 90° coupler 90 is disposed between a matching circuit 22 and inductors 981 and 982.

The 90° coupler 90 includes capacitors 91 and 92, inductors 93 and 94, and a resistance element 95. The capacitor 91 has a first end connected to the matching circuit 22 and a second end connected to the inductor 981. The inductor 93 has a first end connected to the first end of the capacitor 91 and a second end connected to the inductor 982. The inductor 94 has a first end connected to the second end of the capacitor 91 and a second end connected to the ground through the resistance element 95. The capacitor 92 has a first end connected to the second end of the inductor 93 and a second end connected to the second end of the inductor 94.

### BRIEF SUMMARY OF THE DISCLOSURE

For example, in the case where the 90° coupler 90 splits a radio frequency signal having a low frequency, impedance matching with a circuit having a low characteristic impedance may demand an increase of the electrostatic capacity of a capacitor. This results in an increase of the circuit size of the 90° coupler 90.

The present disclosure is made in view of such a situation, and a possible benefit thereof is to provide a 90° coupler which allows a reduction of circuit size.

A 90° coupler according to an aspect of the present disclosure includes a first capacitor that has a first end connected to a first terminal and a second end connected to a first amplifier; a first inductor that has a first end connected to the first terminal and a second end connected to a second amplifier; a second inductor that has a first end connected to the second end of the first capacitor and a second end connected to the ground through a resistance element, and that electromagnetically couples to the first inductor; and a second capacitor that has a first end connected to the first terminal and a second end connected to the second end of the second inductor.

The present disclosure may provide a 90° coupler which allows a reduction of circuit size.

### BRIEF DESCRIPTION OF THE SEVERAL VIEWS OF THE DRAWINGS

FIG. 1 is a circuit diagram of a power amplifier circuit 101;

FIG. 2 is a circuit diagram of a power amplifier circuit 901 which is a reference example;

FIG. 3 is a diagram illustrating frequency variations of the difference between the phase of an amplified signal RF3 at port P2 and that of an amplified signal RF2 at port P3 in a 90° coupler 70;

FIG. 4 is a diagram illustrating frequency variations of the difference between the phase of an amplified signal RF3 at port P2 and that of an amplified signal RF2 at port P3 in a 90° coupler 90;

FIG. 5 is a diagram illustrating frequency variations of loss in the 90° coupler 70;

FIG. 6 is a diagram illustrating frequency variations of loss in the 90° coupler 90;

FIG. 7 is a circuit diagram of a power amplifier circuit 102;

FIG. 8 is a diagram illustrating frequency variations of loss obtained when the electrostatic capacity of a capacitor 92 is made smaller than that of a capacitor 91 in the 90° coupler 90; and

FIG. 9 is a diagram illustrating frequency variations of the difference between the phase of an amplified signal RF3 at port P2 and that of an amplified signal RF2 at port P3, which is obtained when the electrostatic capacity of the capacitor 92 is made smaller than that of the capacitor 91 in the 90° coupler 90.

### DETAILED DESCRIPTION OF THE DISCLOSURE

Embodiments of the present disclosure will be described in detail below by referring to the drawings. The same components are designated with the same reference numerals, and repeated description will be avoided as much as possible.

### First Embodiment

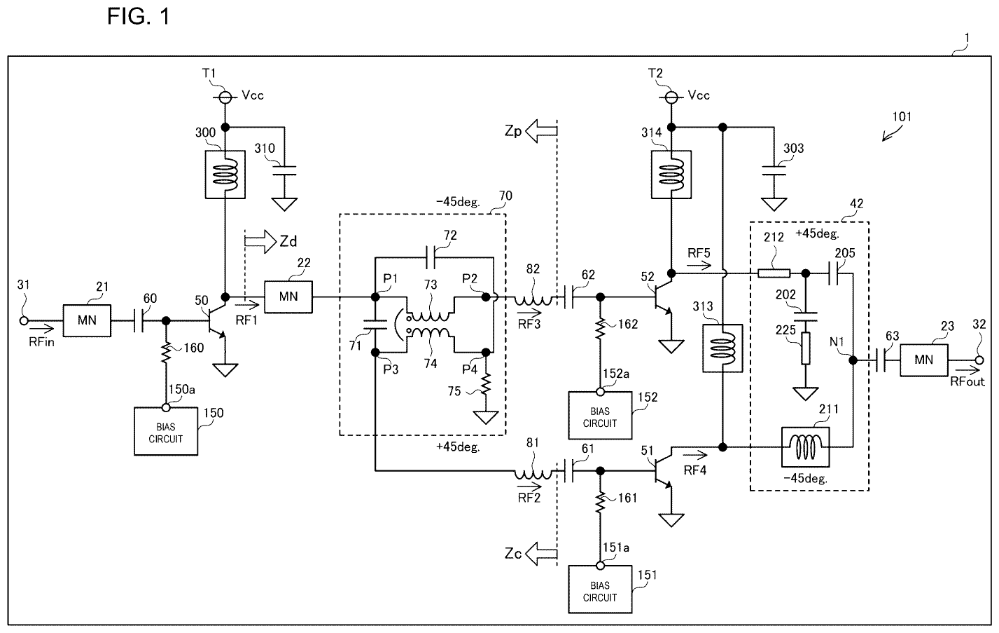

A power amplifier circuit 101 according to a first embodiment will be described. FIG. 1 is a circuit diagram of the power amplifier circuit 101. As illustrated in FIG. 1, a semiconductor device 1 includes the power amplifier circuit 101. The semiconductor device 1 is, for example, a semiconductor chip in or on which the power amplifier circuit 101 is formed. Specifically, the semiconductor device 1 is a microwave monolithic integrated circuit (MMIC). The power amplifier circuit 101 is a circuit which operates as a Doherty amplifier or a balanced amplifier which amplifies radio frequency signals.

The power amplifier circuit 101 includes capacitors 60, 61, 62, 63, 303, and 310, matching circuits 21, 22, and 23, a combining circuit 42, transistor elements 50, 51 (first amplifier), and 52 (second amplifier), a 90° coupler 70, inductors 81 (third inductor) and 82 (fourth inductor), bias circuits 150, 151, and 152, resistance elements 160, 161, and 162, and inductors 300, 313, and 314.

In the present embodiment, each transistor element is formed, for example, of a bipolar transistor such as a heterojunction bipolar transistor (HBT). Each transistor element may be formed of another type of transistor such as a metal-oxide-semiconductor field-effect transistor (MOSFET). In this case, the base, collector, and emitter may be read as the gate, drain, and source, respectively.

The matching circuit 21 in the power amplifier circuit 101 is disposed between an input terminal 31 (first terminal) and the capacitor 60, and matches the impedance between a circuit (not illustrated), which is disposed upstream of the input terminal 31, and the capacitor 60. The capacitor 60, which is provided, for example, for direct current (DC) cutting, has a first end connected to the input terminal 31 through the matching circuit 21 and a second end.

The transistor element 50 is a driver-stage amplifier. In more detail, the transistor element 50 has a base connected to the second end of the capacitor 60, an emitter connected to the ground, and a collector. The transistor element 50 amplifies an input signal RFin supplied to the base from the input terminal 31 through the matching circuit 21 and the capacitor 60, and outputs an amplified signal RF1 from the collector. The input signal RFin is, for example, a radio frequency signal.

The bias circuit 150 generates a bias that is to be supplied to the base of the transistor element 50, for outputting from a bias supply terminal 150a. The bias supply terminal 150a is connected to the base of the transistor element 50 through the resistance element 160.

A voltage supply terminal T1 supplies power supply voltage Vcc for operating the transistor element 50, and is connected to the collector of the transistor element 50 through the inductor 300. The capacitor 310, which is disposed between the voltage supply terminal T1 and the ground, functions as a filter for attenuating harmonic waves.

The matching circuit 22 has a first end connected to the collector of the transistor element 50 and a second end. The matching circuit 22 matches the impedance between the transistor element 50 and the 90° coupler 70.

The 90° coupler 70 has ports P1, P2, P3, and P4. Port P1 is an input port, and port P4 is an isolation port. Ports P2 and P3 are output ports. In the present embodiment, the 90° coupler 70 functions as a splitting circuit.

Port P1 is connected to the second end of the matching circuit 22. Port P1 is supplied with the amplified signal RF1 (first signal) through the matching circuit 22 from the collector of the transistor element 50.

The 90° coupler 70 splits the amplified signal RF1, which is supplied to port P1, into an amplified signal RF2 (second signal) and an amplified signal RF3 (third signal).

The amplified signal RF3 has a phase delayed from that of the amplified signal RF2 by greater than or equal to 45° and less than or equal to 135°. In the present embodiment, the amplified signal RF3 has a phase delayed from that of the amplified signal RF2 by about 90°.

Port P3 supplies the amplified signal RF2 to the input terminal of the transistor element 51. Port P2 supplies the amplified signal RF3 to the input terminal of the transistor element 52.

More specifically, the 90° coupler 70 includes capacitors 71 (first capacitor) and 72 (second capacitor), inductors 73 (first inductor) and 74 (second inductor), and a resistance element 75.

The capacitor 71 has a first end connected to the second end of the matching circuit 22 and a second end connected to the transistor element 51 through the inductor 81 and the capacitor 61.

The inductor 73 has a first end connected to the second end of the matching circuit 22 and a second end connected to the transistor element 52 through the inductor 82 and the capacitor 62.

The inductor 74 has a first end connected to the second end of the capacitor 71 and a second end grounded through the resistance element 75, and electromagnetically couples to the inductor 73. The coupling coefficient k between the inductors 73 and 74 is, for example, 0.8.

The capacitor 72 has a first end connected to the second end of the matching circuit 22 and a second end connected to the second end of the inductor 74.

The first end of the capacitor 71, the first end of the inductor 73, and the first end of the capacitor 72 correspond to port P1. The second end of the capacitor 71 and the first end of the inductor 74 correspond to port P3. The second end of the inductor 73 corresponds to port P2. The second end of the inductor 74 and the second end of the capacitor 72 correspond to port P4.

The electrostatic capacity of the capacitor 72 is smaller than that of the capacitor 71. In the present embodiment, the electrostatic capacities of the capacitors 72 and 71 are, for example, 5 pF and 15 pF, respectively. That is, the electrostatic capacity of the capacitor 72 is the order of one third of that of the capacitor 71. Thus, the area of each of the two electrodes included in the capacitor 72 may be reduced, achieving a reduction of the circuit size of the 90° coupler 70.

The inductor 81 is disposed between the second end of the capacitor 71 and the transistor element 51. In more detail, the inductor 81 has a first end connected to the second end of the capacitor 71 and a second end connected to the base of the transistor element 51 through the capacitor 61. The capacitor 61 is provided, for example, for DC cutting.

The inductor 82 is disposed between the second end of the inductor 73 and the transistor element 52. In more detail, the inductor 82 has a first end connected to the second end of the inductor 73 and a second end connected to the base of the transistor element 52 through the capacitor 62. The capacitor 62 is provided, for example, for DC cutting.

The transistor element 51 is a carrier amplifier. In more detail, the transistor element 51 has a base (input terminal), an emitter connected to the ground, and a collector. The transistor element 51 amplifies the amplified signal RF2 supplied to the base through the inductor 81 and the capacitor 61 from port P3 of the 90° coupler 70, and outputs an amplified signal RF4 from the collector.

The bias circuit 151 generates a first bias that is to be supplied to the base of the transistor element 51 through the resistance element 161, for outputting from a bias supply terminal 151a. The bias supply terminal 151a is connected to the base of the transistor element 51 through the resistance element 161. In the present embodiment, the transistor element 51 performs class A operation or class AB operation in accordance with the first bias supplied from the bias circuit 151.

The transistor element 52 is a peak amplifier. In more detail, the transistor element 52 has a base (input terminal), an emitter connected to the ground, and a collector. The transistor element 52 amplifies the amplified signal RF3 supplied to the base through the inductor 82 and the capacitor 62 from port P2 of the 90° coupler 70, and outputs an amplified signal RF5 from the collector.

The bias circuit 152 generates a low bias or a high bias that is to be supplied to the base of the transistor element 52 through the resistance element 162, for outputting from a bias supply terminal 152a. The bias supply terminal 152a is connected to the base of the transistor element 52 through the resistance element 162.

In the present embodiment, the bias circuit 152 switches, for example, the bias point (operating point or operating class) of the transistor element 52 between a low bias point and a high bias point which is higher than the low bias point. For example, the bias circuit 152 supplies, to the transistor element 52, either one of the low bias and the high bias which is higher than the low bias.

When the high bias is supplied to the transistor element 52, the power amplifier circuit 101 enters the balance mode. At that time, the bias point of the transistor element 52 is the high bias point. Thus, the transistor element 52 performs, for example, class A operation or class AB operation. This causes the power amplifier circuit 101 to operate as a balanced amplifier.

In contrast, when the low bias is supplied to the transistor element 52, the power amplifier circuit 101 enters the Doherty mode. At that time, the bias point of the transistor element 52 is the low bias point. Thus, the transistor element 52 performs, for example, class AB operation or class B operation. This causes the power amplifier circuit 101 to operate as a Doherty amplifier.

A voltage supply terminal T2 supplies power supply voltage Vcc for operating the transistor elements 51 and 52, and is connected to the collector of the transistor element 51 and the collector of the transistor element 52 through the inductors 313 and 314, respectively. The capacitor 303, which is disposed between the voltage supply terminal T2 and the ground, functions as a filter for attenuating harmonic waves.

The combining circuit 42 reduces the phase difference between the amplified signals RF4 and RF5 which are supplied from the transistor elements 51 and 52, respectively, and combines the amplified signals RF4 and RF5 to generate an output signal RFout. The combining circuit 42 outputs the output signal RFout to an output terminal 32 through the capacitor 63 and the matching circuit 23.

In the present embodiment, the combining circuit 42 includes capacitors 202 and 205 and inductors 211, 212, and 225.

The inductor 212 has a first end connected to the collector of the transistor element 52 and a second end. The inductor 225 has a first end connected to the second end of the inductor 212 through the capacitor 202 and a second end connected to the ground. The capacitor 205 has a first end connected to the second end of the inductor 212 and a second end connected to node N1. The inductor 211 has a first end connected to the collector of the transistor element 51 and a second end connected to node N1.

The capacitor 63, which is provided for DC cutting, has a first end connected to node N1 and a second end.

The matching circuit 23, which is disposed between the capacitor 63 and the output terminal 32, matches the impedance between the capacitor 63 and a circuit (not illustrated) disposed downstream of the output terminal 32.

### Reference Example

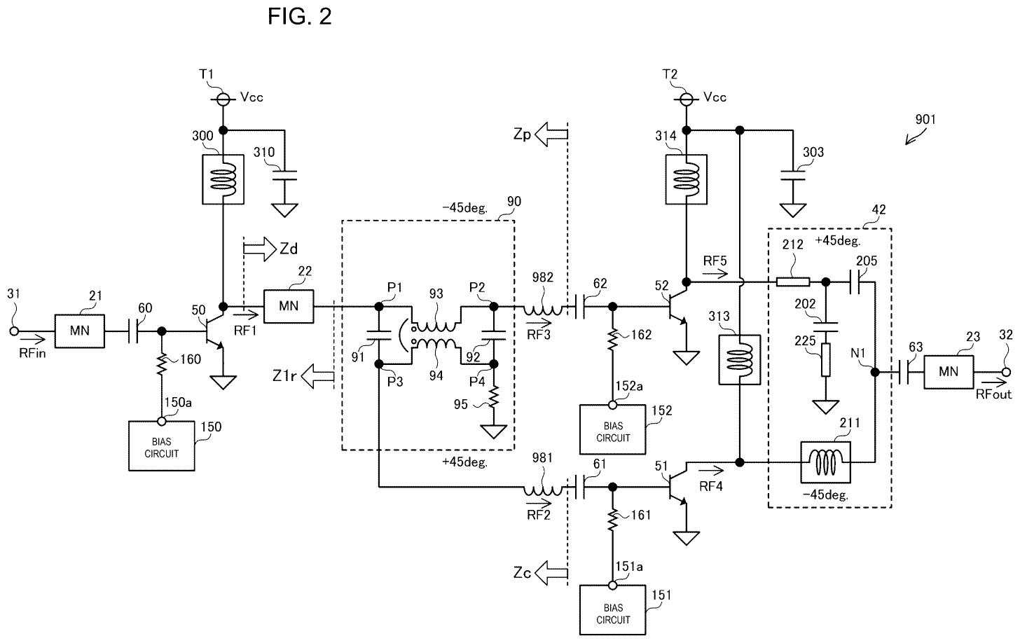

The power amplifier circuit 901, which is a reference example, will be described. FIG. 2 is a circuit diagram of the power amplifier circuit 901 which is a reference example. Compared with the power amplifier circuit 101 in FIG. 1, the power amplifier circuit 901 includes the 90° coupler 90 and the inductors 981 and 982 instead of the 90° coupler 70 and the inductors 81 and 82.

As described above, in the 90° coupler 70, the first end of the capacitor 72 is connected to the first end of the inductor 73. In contrast, in the 90° coupler 90, the first end of the capacitor 92 is connected to the second end of the inductor 93.

The coupling coefficient k between the inductors 93 and 94 is, for example, 0.8. The electrostatic capacity of the capacitor 92 is approximately the same as that of the capacitor 91. In the reference example, the electrostatic capacity of each of the capacitors 91 and 92 is, for example, 15 pF. That is, the electrostatic capacity of the capacitor 92 is the order of three times that of the capacitor 72. This results in an increase of the circuit size of the 90° coupler 90.

### Effect

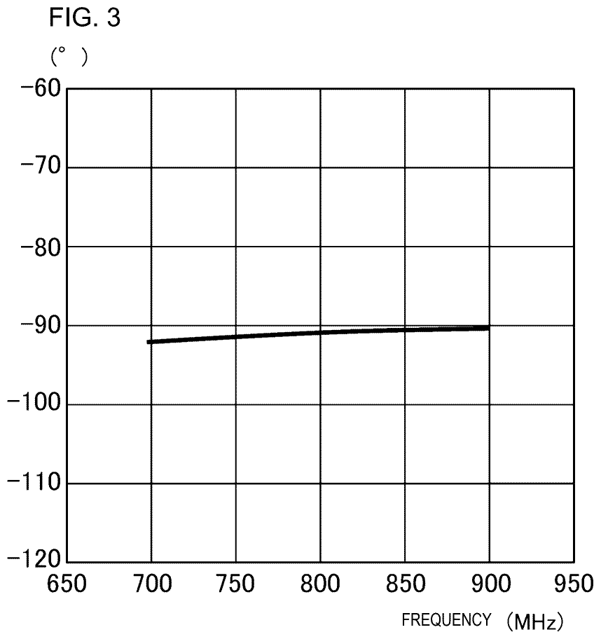

FIG. 3 is a diagram illustrating frequency variations of the difference between the phase of the amplified signal RF3 at port P2 and that of the amplified signal RF2 at port P3 in the 90° coupler 70. The vertical axis indicates the phase difference of a unit of “o”. The horizontal axis indicates the frequency of a unit of “MHz”.

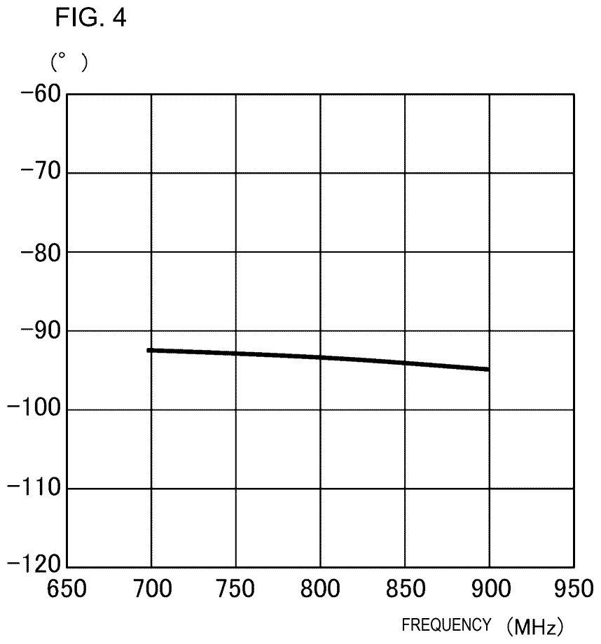

FIG. 4 is a diagram illustrating frequency variations of the difference between the phase of the amplified signal RF3 at port P2 and that of the amplified signal RF2 at port P3 in the 90° coupler 90. Reading of FIG. 4 is substantially the same as that of FIG. 3.

As illustrated in FIGS. 3 and 4, in the power amplifier circuit 101, the phase difference between the amplified signal RF3 and the amplified signal RF2 is about-90°, which indicates that the 90° coupler 70 functions as an excellent splitting circuit as well as or better than the 90° coupler 90.

In the power amplifier circuits 101 and 901, the impedance Zc (see FIGS. 1 and 2) as seen from a first end of the capacitor 61 to the input terminal 31 side may be, for example, the order of 8+j×10 ohms, where j is the imaginary unit.

The impedance Zp (see FIGS. 1 and 2) as seen from a first end of the capacitor 62 to the input terminal 31 side may be, for example, the order of 8+j×10 ohms.

The impedance Zd (see FIGS. 1 and 2) as seen from the collector of the transistor element 50 to the output terminal 32 side may be, for example, the order of 30 to 50 ohms.

For example, in the case of a reference impedance of eight ohms, the scattering(S) parameter (hereinafter may be referred to as S33) at port P3 (see FIG. 1) in the 90° coupler 70 may contain more positive imaginary components than the S parameter (hereinafter may be referred to as S33r) at port P3 (see FIG. 2) in the 90° coupler 90.

Thus, the inductance of the inductor 81 (see FIG. 1) which matches the impedance between the 90° coupler 70 and the capacitor 61 may be made smaller than that of the inductor 981 (see FIG. 2) which matches the impedance between the 90° coupler 90 and the capacitor 61.

Specifically, the inductance of the inductor 81 and that of the inductor 981 are 1.4 nH and 1.6 nH, respectively. Thus, the circuit size of the inductor 81 may be made smaller than that of the inductor 981.

For example, in the case of a reference impedance of eight ohms, the S parameter (hereinafter may be referred to as S22) at port P2 (see FIG. 1) in the 90° coupler 70 may contain even more positive imaginary components than the S parameter (hereinafter may referred to as S22r) at port P2 (see FIG. 2) in the 90° coupler 90.

Thus, the inductance of the inductor 82 (see FIG. 1) which matches the impedance between the 90° coupler 70 and the capacitor 62 may be made smaller than that of the inductor 982 (see FIG. 2) which matches the impedance between the 90° coupler 90 and the capacitor 62. Specifically, the inductance of the inductor 82 and

that of the inductor 982 are 1.3 nH and 1.8 nH, respectively. Thus, the circuit size of the inductor 82 may be made smaller than that of the inductor 982.

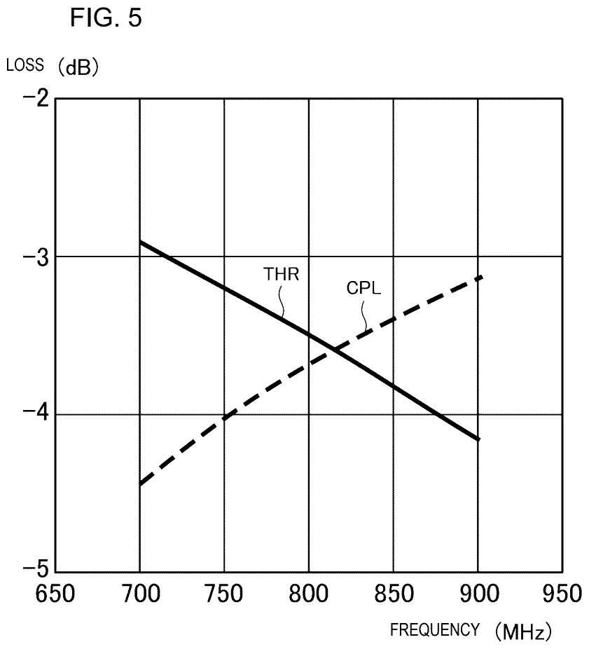

FIG. 5 is a diagram illustrating frequency variations of loss in the 90° coupler 70. The vertical axis indicates the loss of a unit of “dBm”. The horizontal axis indicates the frequency of a unit of “MHz”.

As illustrated in FIG. 5, curve THR illustrates frequency variations of loss obtained when a radio frequency signal passes through a path from port P1 through the inductor 73, port P2, and the inductor 82 to the capacitor 62 in the power amplifier circuit 101 (see FIG. 1).

Curve CPL illustrates frequency variations of loss obtained when a radio frequency signal passes through a path from port P1 through the capacitor 71, port P3, and the inductor 81 to the capacitor 61 in the power amplifier circuit 101 (see FIG. 1).

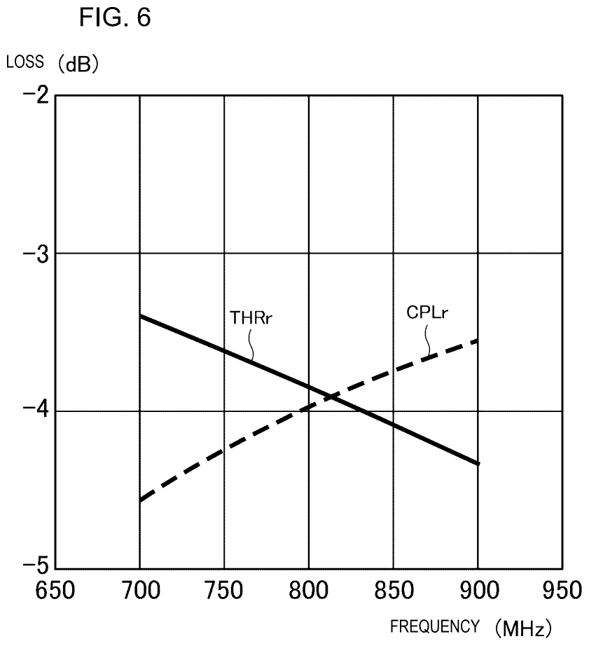

FIG. 6 is a diagram illustrating frequency variations of loss in the 90° coupler 90. Reading of FIG. 6 is substantially the same as that of FIG. 5.

As illustrated in FIG. 6, curve THRr illustrates frequency variations of loss obtained when a radio frequency signal passes through a path from port P1 through the inductor 93, port P2, and the inductor 982 to the capacitor 62 in the power amplifier circuit 901 (see FIG. 2).

Curve CPLr illustrates frequency variations of loss obtained when a radio frequency signal passes through a path from port P1 through the capacitor 91, port P3, and the inductor 981 to the capacitor 61 in the power amplifier circuit 901 (see FIG. 2).

As described above, S33 contains even more positive imaginary components than S33r. Thus, the amount of impedance conversion by the inductor 81 may be made smaller than that by the inductor 981, achieving improvement of the loss indicated by curve CPL, compared with the loss indicated by curve CPLr.

S22 contains even more positive imaginary components than S22r. Thus, the amount of impedance conversion by the inductor 82 may be smaller than that by the inductor 982, achieving improvement of the loss indicated by curve THR, compared with the loss indicated by curve THRr.

### Second Embodiment

A power amplifier circuit 102 according to a second embodiment will be described. In the second embodiment and its subsequent embodiments, points common to those in the first embodiment will not be described, and only different points will be described. In particular, substantially the same operational effects caused by substantially the same configurations will not be described in each embodiment.

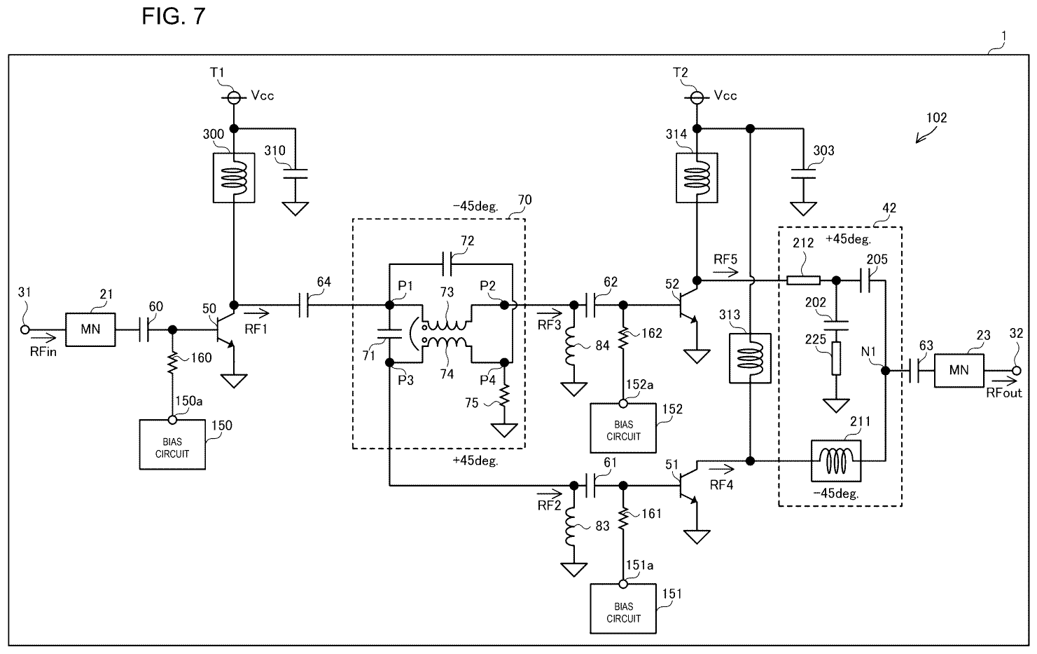

FIG. 7 is a circuit diagram of the power amplifier circuit 102. As illustrated in FIG. 7, the power amplifier circuit 102 is different from the power amplifier circuit 101 according to the first embodiment in that a capacitor 64 and inductors 83 and 84 are included instead of the matching circuit 22 and the inductors 81 and 82.

The capacitor 64 has a first end connected to the collector of the transistor element 50 and a second end connected to the first end of the capacitor 71 in the 90° coupler 70. The capacitor 64 matches the impedance between the transistor element 50 and the 90° coupler 70.

The inductor 83 has a first end connected to the second end of the capacitor 71 and a second end connected to the ground.

The inductor 84 has a first end connected to the second end of the inductor 73 and a second end connected to the ground.

In the embodiment described in the present specification, the example in which the 90° coupler 70 functions as a splitting circuit is described. A 90° coupler in the present disclosure may be applied not only to a splitting circuit but also to a combining circuit. Specifically, instead of the combining circuit 42, there may be provided a 90° coupler 70 which combines the amplified signals RF4 and RF5 with each other to generate the output signal RFout. In this case, ports P2 and P3 in the 90° coupler 70 are input terminals; port P1 is an output terminal.

In the present embodiment, the configuration in which the electrostatic capacity of the capacitor 72 is smaller than that of the capacitor 71 is described.

However, the configuration is not limited to this. The electrostatic capacity of the capacitor 72 may be larger than or equal to that of the capacitor 71.

The embodiment examples of the present disclosure are described above. In the power amplifier circuits 101 and 102, the 90° coupler 70 includes the capacitors 71 and 72, the inductors 73 and 74, and the resistance element 75. The capacitor 71 has the first end connected to the input terminal 31 and the second end connected to the transistor element 51. The inductor 73 has the first end connected to the input terminal 31 and the second end connected to the transistor element 52. The inductor 74 has the first end connected to the second end of the capacitor 71 and the second end connected to the ground through the resistance element 75, and electromagnetically couples to the inductor 73. The capacitor 72 has the first end connected to the input terminal 31 and the second end connected to the second end of the inductor 74.

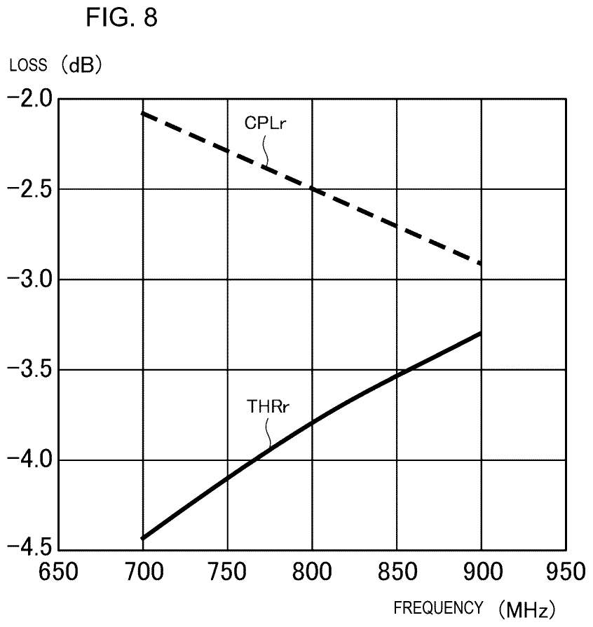

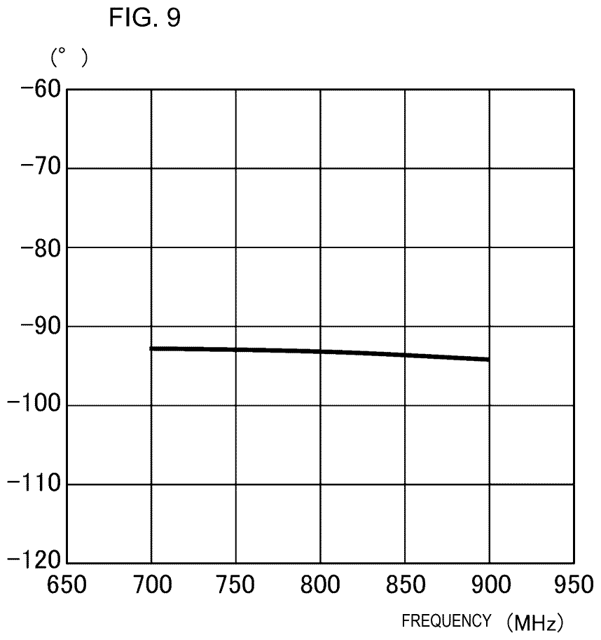

FIG. 8 is a diagram illustrating frequency variations of loss obtained when the electrostatic capacity of the capacitor 92 is made smaller than that of the capacitor 91 in the 90° coupler 90. Reading of FIG. 8 is substantially the same as that of FIG. 5. FIG. 9 is a diagram illustrating frequency variations of the difference between the phase of the amplified signal RF3 at port P2 and that of the amplified signal RF2 at port P3, which is obtained when the electrostatic capacity of the capacitor 92 is made smaller than that of the capacitor 91 in the 90° coupler 90. Reading of FIG. 9 is substantially the same as that of FIG. 3. As illustrated in FIGS. 8 and 9, for example, when the electrostatic capacity of the capacitor 92 is made smaller than that of the capacitor 91 in the 90° coupler 90, more imaginary components may be contained in S22r and S33r. In contrast, the difference between curve THRr and curve CPLr is remarkably large on the low frequency side, resulting in degradation in balancing. In addition, the phase difference between the amplified signal RF3 and the amplified signal RF2 deviates from −90°. Therefore, just a reduction of the electrostatic capacity of the capacitor 92 in the 90° coupler 90 makes it difficult for the 90° coupler 90 to function as an excellent splitting circuit and combining circuit. The inventor studied diligently to solve the issue, and found that the configuration of asymmetric connection in which the first end of the capacitor 72 is connected to the first end of the inductor 73, not symmetric connection in which the first end of the capacitor 72 is connected to the second end of the inductor 73, enables the 90° coupler 70 to function as an excellent splitting circuit or combining circuit while the electrostatic capacity of the capacitor 71 or 72 is made small. Thus, a 90° coupler which allows a reduction of circuit size may be provided.

In the power amplifier circuits 101 and 102, the electrostatic capacity of the capacitor 72 is smaller than that of the capacitor 71.

Thus, the configuration in which the electrostatic capacity of the capacitor 72 is smaller than that of the capacitor 71 enables the 90° coupler 70 to function as an excellent splitting circuit in a Doherty amplifier and a balanced amplifier.

In the power amplifier circuit 101, the second end of the capacitor 71 is connected to the transistor element 51 through the inductor 81. The second end of the inductor 73 is connected to the transistor element 52 through the inductor 82.

This configuration enables the inductor 81 to match the impedance between the 90° coupler 70 and the transistor element 51 satisfactorily. The inductance of the inductor 81 may be made smaller, achieving a reduction of the circuit size of the inductor 81. The inductor 82 may match the impedance between the 90° coupler 70 and the transistor element 52 satisfactorily. The inductance of the inductor 82 may be made smaller, achieving a reduction of the circuit size of the inductor 82.

In the power amplifier circuits 101 and 102, the first end of the capacitor 71 is supplied with the amplified signal RF1 from the input terminal 31. The second end of the capacitor 71 supplies the amplified signal RF2 to the input terminal of the transistor element 51. The second end of the inductor 73 supplies, to the input terminal of the transistor element 52, the amplified signal RF3 having a phase delayed from the phase of the amplified signal RF2 by greater than or equal to 45° and less than or equal to 135°.

This configuration enables the 90° coupler 70 to function as an excellent splitting circuit which splits the amplified signal RF1 into the amplified signals RF2 and RF3.

The embodiments described above are made to facilitate understanding of the present disclosure, not to interpret the present disclosure limitedly. The present disclosure may be changed/improved without departing from the gist thereof, and the equivalents are encompassed in the present disclosure. That is, embodiments obtained by those skilled in the art adding changes appropriately to the embodiments are encompassed in the scope of the present disclosure as long as having features of the present disclosure. For example, the components included in the embodiments and their layouts, materials, conditions, shapes, sizes, and the like are not limited to illustrated ones, and may be changed appropriately. The embodiments are examples. Needless to say, partial replacement or combination of the configurations described in different embodiments may be made. These are also encompassed in the scope of the present disclosure as long as having features of the present disclosure.

<1> A 90° coupler comprising: a first capacitor that has a first end connected to a first terminal and a second end connected to a first amplifier; a first inductor that has a first end connected to the first terminal and a second end connected to a second amplifier; a second inductor that has a first end connected to the second end of the first capacitor and a second end connected to a ground through a resistance element, and that electromagnetically couples to the first inductor; and a second capacitor that has a first end connected to the first terminal and a second end connected to the second end of the second inductor.

<2> The 90° coupler according to <1>, wherein the second capacitor is smaller in electrostatic capacity than the first capacitor.

<3> The 90° coupler according to <1> or <2>, wherein the second end of the first capacitor is connected to the first amplifier through a third inductor, and wherein the second end of the first inductor is connected to the second amplifier through a fourth inductor.

<4> The 90° coupler according to any one of <1> to <3>, wherein the first end of the first capacitor is supplied with a first signal from the first terminal, wherein the second end of the first capacitor supplies a second signal to an input terminal of the first amplifier, and wherein the second end of the first inductor supplies a third signal to an input terminal of the second amplifier, the third signal being delayed in phase from the second signal by greater than or equal to 45° and less than or equal to 135°.

What is claimed is:

1. A 90° coupler comprising:
a first capacitor that has a first end connected to a first terminal and a second end connected to a first amplifier;
a first inductor that has a first end connected to the first terminal and a second end connected to a second amplifier;
a second inductor that has a first end connected to the second end of the first capacitor and a second end connected to ground through a resistance circuit element, and that is electromagnetically coupled to the first inductor; and
a second capacitor that has a first end connected to the first terminal and a second end connected to the second end of the second inductor.

2. The 90° coupler according to claim 1, wherein the second capacitor has a smaller electrostatic capacity than the first capacitor.

3. The 90° coupler according to claim 1,
wherein the second end of the first capacitor is connected to the first amplifier through a third inductor, and
wherein the second end of the first inductor is connected to the second amplifier through a fourth inductor.

4. The 90° coupler according to claim 1,
wherein the first end of the first capacitor is supplied with a first signal from the first terminal,
wherein the second end of the first capacitor supplies a second signal to an input terminal of the first amplifier, and
wherein the second end of the first inductor supplies a third signal to an input terminal of the second amplifier, the third signal being delayed in phase from the second signal by greater than or equal to 45° and less than or equal to 135°.
